(19) United States
(12) Patent Application Publication
(10) Pub. No.: US 2013/0109197 A1
(43) Pub. Date: May 2, 2013

(54) METHOD OF FORMING SILICON OXIDE FILM

(71) Applicant: TOKYO ELECTRON LIMITED, Tokyo (JP)

(72) Inventors: Hiroki MURAKAMI, Nirasaki City (JP); Toshiyuki IKEUCHI, Nirasaki City (JP); Jun SATO, Nirasaki City (JP); Yuichiro MOROZUMI, Nirasaki City (JP); Kazuhide HASEBE, Nirasaki City (JP)

(73) Assignee: TOKYO ELECTRON LIMITED, Tokyo (JP)

(21) Appl. No.: 13/661,148

(22) Filed: Oct. 26, 2012

(30) Foreign Application Priority Data
Oct. 28, 2011 (JP) 2011-237977
Sep. 18, 2012 (JP) 2012-204155

(51) Int. Cl. H01L 21/316

(52) U.S. Cl. 438/770; 257/E21.285

(57) ABSTRACT

A method of forming a silicon oxide film includes forming a seed layer on a base, forming a silicon film on the seed layer, and forming the silicon oxide film on the base by oxidizing the silicon film and the seed layer.

### CROSS-REFERENCE TO RELATED PATENT APPLICATIONS

This application claims the benefits of Japanese Patent Application No. 2011-237977, filed on Oct. 28, 2011 and Japanese Patent Application No. 2012-204155, filed on Sep. 18. 2012 in the Japan Patent Office, the disclosures of which are incorporated herein in its entirety by reference.

### BACKGROUND OF THE INVENTION

1. Field of the Invention

The present invention relates to a method of forming a silicon oxide film.

2. Description of the Related Art

Recently, semiconductor integrated circuit apparatuses have been is miniaturized. According to such miniaturization, various thin films used in the semiconductor integrated circuit apparatuses are required to be further thinned and to have better film quality.

For example, Patent Reference 1 discloses a method of forming an insulating film, such as a thin oxide film.

For further thinning of a film, it is important to improve a surface roughness of a thin film because when a surface roughness is low, it is difficult to obtain a uniform film thickness despite of thinning.

Also, as a new task required in a thin film, it is also important to improve an interface roughness with a base. When the interface roughness is low, an interface level is generated on an interface between the base and the thin film, and thus a mobility of electrons or holes may be deteriorated or charges may be trapped.

Patent Reference 1 discloses forming a thin oxide film or improving electric characteristics of the thin oxide film, but does not disclose improving a surface roughness and improving an interface roughness.

3. Prior Art Reference

(Patent Reference 1) Japanese Patent Laid-Open Publication No. 2003-297822

### SUMMARY OF THE INVENTION

The present invention provides a method of forming a silicon oxide film, which is capable of obtaining a silicon oxide film having satisfactory surface roughness, a satisfactory interface roughness, or both the satisfactory surface roughness and the satisfactory interface roughness.

According to an aspect of the present invention, there is provided a method of forming a silicon oxide film, the method including: forming a seed layer on a base; forming a silicon film on the seed layer; and forming a silicon oxide film on the base by oxidizing the silicon film and the seed layer.

According to another aspect of the present invention, there is provided a method of forming a silicon oxide film, the method including: forming an amorphous silicon film on a base; increasing a temperature up to an oxidation temperature while supplying hydrogen to the amorphous silicon film; and forming a silicon oxide film on the base by oxidizing the amorphous silicon film to which the hydrogen is supplied at the oxidation temperature.

According to another aspect of the present invention, there is provided a method of forming a silicon oxide film, the method including: forming an amorphous silicon film on a base; performing a re-crystallization suppressing process on the amorphous silicon film under an atmosphere containing oxygen; and forming a silicon oxide film on the base by oxidizing the amorphous silicon film on which the re-crystallization suppressing process is performed.

According to another aspect of the present invention, there is provided a method of forming a silicon oxide film, the method including: forming an amorphous silicon film on a base while introducing oxygen; and forming a silicon oxide film on the base by oxidizing the amorphous silicon film formed while introducing the oxygen.

According to another aspect of the present invention, there is provided a method of forming a silicon oxide film, the method including: forming an amorphous silicon film on a base; and forming a silicon oxide film on the base by oxidizing the amorphous silicon film at a temperature lower than a crystallization temperature of the amorphous silicon film.

According to another aspect of the present invention, there is provided a method of forming a silicon oxide film, the method including: forming a blocking film, which blocks a progression of crystal growth, on a base; forming an amorphous silicon film on the blocking film; and forming a silicon oxide film on the blocking film by oxidizing the amorphous silicon film.

Additional objects and advantages of the invention will be set forth in the description which follows, and in part will be obvious from the description, or may be learned by practice of the invention.

The objects and advantages of the invention may be realized and obtained by means of the instrumentalities and combinations particularly pointed out hereinafter.

### BRIEF DESCRIPTION OF THE DRAWINGS

The accompanying drawings, which are incorporated in and constitute a part of the specification, illustrate embodiments of the invention, and together with the general description given above and the detailed description of the embodiments given below, serve to explain the principles of the invention.

FIG. 1 is a flowchart showing an example of a method of forming a silicon is oxide film, according to an embodiment of the present invention;

FIGS. 2A through 2C are cross-sectional views for describing main processes of the method of FIG. 1;

FIG. 3 is a diagram of surface roughness;

FIG. 4 is a timing chart for describing an example of a method of forming a silicon oxide film, according to another embodiment of the present invention;

FIGS. 5A through 5C are cross-sectional views for describing main processes of the method of FIG. 4;

FIG. 6 is a timing chart for describing an example of a method of forming a silicon oxide film, according to another embodiment of the present invention:

FIGS. 7A through 7C are cross-sectional views for describing main processes of the method of FIG. 6;

FIG. 8 is a cross-sectional view for describing a modified example of the method of FIG. 6;

FIG. 9 is a diagram of surface roughness;

FIG. 10 is a flowchart showing an example of a method of forming a silicon oxide film, according to another embodiment of the present invention;

FIGS. 11A and 11B are cross-sectional views for describing main processes of the method of FIG. 10: FIG. 12 is a timing chart for describing an example of a method of forming a silicon oxide film, according to another embodiment of the present invention;

FIG. 13 is a diagram for describing a relationship between an oxidation temperature and a surface roughness of a silicon oxide film;

FIG. 14 is a timing chart for describing another example of the method of FIG. 12;

FIG. 15 is a flowchart showing a method of forming a silicon oxide film, according to another embodiment of the present invention; and

FIGS. 16A through 16C are cross-sectional views for describing main processes of the method of FIG. 15.

### DETAILED DESCRIPTION OF THE INVENTION

An embodiment of the present invention achieved on the basis of the findings given above will now be described with reference to the accompanying drawings in the following description, the constituent elements having substantially the same function and arrangement are denoted by the same reference numerals, and a repetitive description will be made only when necessary.

Hereinafter, the present invention will be described in detail by explaining exemplary embodiments of the invention with reference to the attached drawings. Like reference numerals in the drawings denote like elements.

### An Embodiment

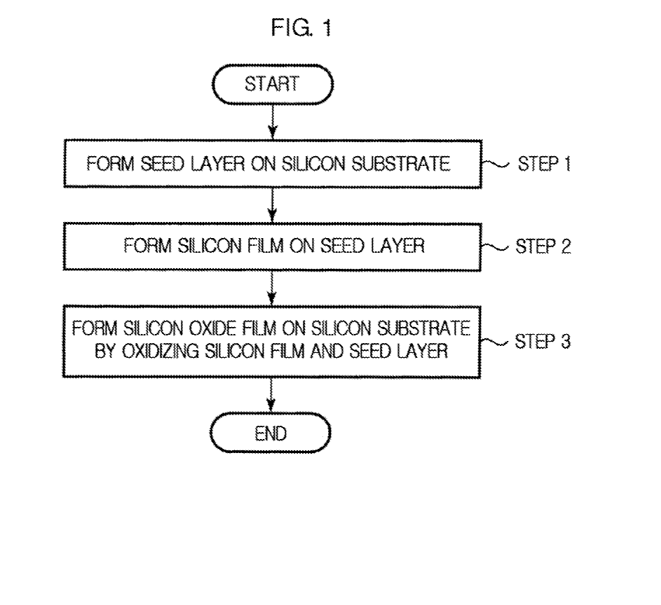

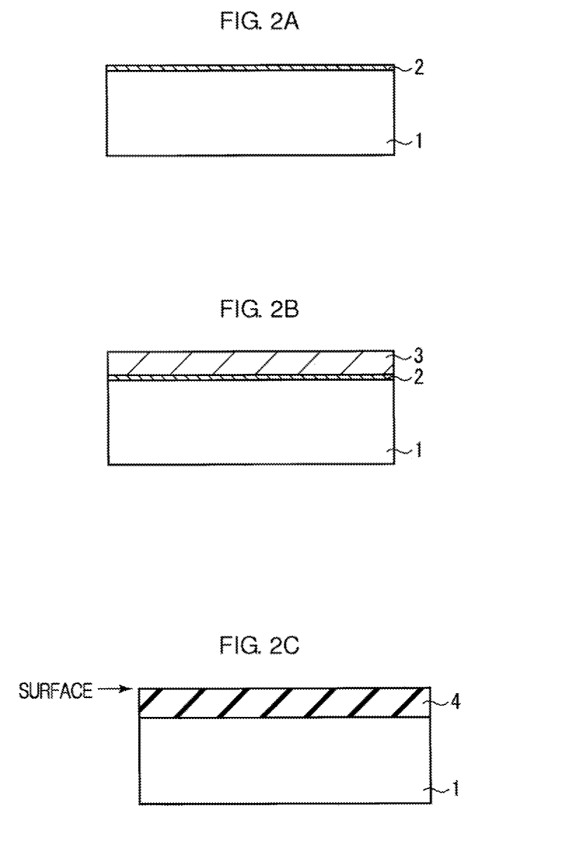

FIG. 1 is a flowchart showing an example of a method of forming a silicon oxide film, according to an embodiment of the present invention, and FIGS. 2A through 2C are cross-sectional views for describing main processes of the method of the present embodiment.

As shown in step 1 of FIG. 1, a seed layer is formed on a base, in the present embodiment, on a silicon substrate (silicon wafer=silicon single crystal). An example of a method of forming a seed layer is as follows:

As shown in FIG. 2A, a silicon substrate 1 is heated, and for example, an aminosilane-based gas as a seed layer raw material gas is flowed on a main surface of the heated silicon substrate 1. Accordingly, a silicon component contained in the aminosilane-based gas is adsorbed on the main surface of the silicon substrate 1, and thus a seed layer 2 is formed on the silicon substrate 1.

Examples of the aminosilane-based gas include gases including at least one of butylaminosilane (BAS), bistertiarybutylaminosilane (BTBAS), dimethylaminosilane (DMAS), bisdimethylaminosilane (BDMAS), tridimethylaminosilane (TDMAS), diethylaminosilane (DEAS), bisdiethylaminosilane (BDEAS), dipropylaminosilane (DPAS), and diisopropylaminosilane (DIPAS). In the present embodiment, DIPAS was used.

An example of process conditions when the seed layer 2 is formed is as follows:

DIPAS Flow Rate: 200 sccm

Process Time: 1 min

Process Temperature: 400° C.

Process Pressure: 133.3 Pa (1 Torr)

The forming of the seed layer 2 is a process of enabling a silicon raw material to be easily adsorbed to a surface of the silicon substrate 1. In the present specification, it is described that the seed layer 2 is formed, but the seed layer 2 is scarcely formed in reality. A thickness of the seed layer 2 may preferably be at a mono-atomic layer level. In detail, the thickness of the seed layer 2 may be from 0.1 nm to 0.3 nm.

Then, as shown in step 2 of FIG. 1 and FIG. 28, a silicon film 3 is formed on the seed layer 2. In detail, the silicon substrate 1 on which the seed layer 2 is formed is heated, and a silicon raw material gas is flowed on the surface of the heated silicon substrate 1. Accordingly, the silicon film 3 is formed on the seed layer 2.

An example of the silicon raw material gas includes a silane-based gas that does not contain an amino group. Examples of the silane-based gas that does not contain an amino group include gases including at least one of SiH₄ and Si₂H₆. In the present embodiment, Si₂H₆ (disilane) was used.

An example of process conditions when the silicon film 3 is formed is as follows:

Disilane Flow Rate: 200 sccm

Process Time: 6 min

Process Temperature: 400° C.

Process Pressure: 133.3 Pa (1 Torr)

In such process conditions, the amorphous silicon film 3 having a thin thickness of about 2 nm is formed. Also, in the present embodiment, the silicon film 3 is formed of amorphous silicon, but alternatively, the silicon film 3 may be formed of nano-crystal silicon in which crystal grains of amorphous to nano sizes are gathered, or silicon in which amorphous silicon and nano-crystal silicon are mixed. In addition, the silicon film 3 may be formed of poly crystal silicon. Here, considering a “surface roughness” of a surface of a silicon oxide film formed afterwards, it is better to select nano-crystal silicon instead of poly crystal silicon, amorphous-nano-crystal mixed silicon instead of nano-crystal silicon, and amorphous silicon instead of amorphous-nano-crystal mixed silicon.

Then, as shown in step 3 of FIG, 1 and FIG. 2C, a silicon oxide film 4 is formed on the silicon substrate 1 by oxidizing the silicon film 3 and the seed layer 2.

An example of process conditions when forming the silicon oxide film 4 is as follows:

Oxidation Method: Depressurization-radical oxidation method

Oxidizing agent: O₂/H₂

Oxidation Time: 30 min

Oxidation Temperature: 600° C.

Process Pressure: 133.3 Pa (1 Torr)

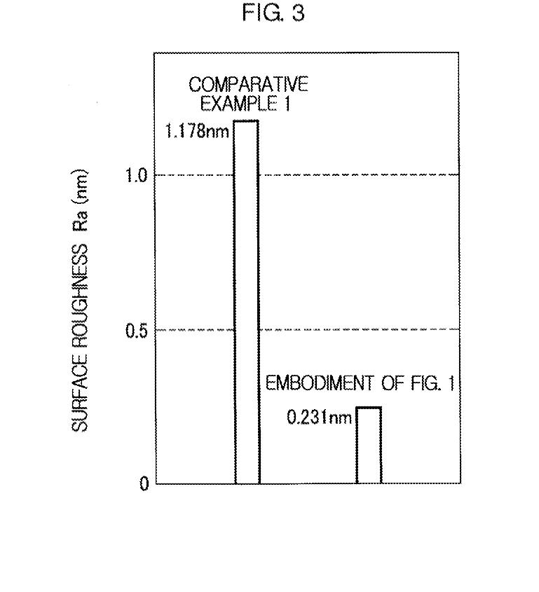

A surface roughness Ra of the silicon oxide film 4 formed as such is measured, and is compared with a surface roughness Ra of a silicon oxide film formed when a seed layer is not formed (Comparative Example 1). The result of the comparison is shown in FIG. 3.

As shown in FIG. 3, the surface roughness Ra of the silicon oxide film of Comparative Example 1 was “Ra=1.178 nm” whereas the surface roughness Ra of the silicon oxide film 4 formed according to the present embodiment was “Ra=0.231 nm”.

As such, according to the method of the present embodiment, the seed layer 2 is formed on the surface of the base as a pre-process before forming the silicon film 3. As such, the silicon oxide film 4 having a satisfactory surface roughness may be obtained.

Also, the surface roughness Ra may be measured as follows:

Measuring Device: Atomic force microscope (AFM)

Measurement Range: 1 μm×1 μm

Roughness: Mean line roughness (Ra)

Also, the present embodiment may be modified as follows:

Modification of Seed Layer Raw Material Gas

A higher-level sane-based gas may be used as the seed layer raw material gas, instead of the aminosilane-based gas.

A higher-level silane-based gas equal to or higher than a trisilane may be used as the higher-silane-based gas. Examples of the higher-level silane-based gas equal to or higher than the trisilane include a hydride of silicon represented by a formula SiₘH₂ₘ₊₂, wherein m is a natural number equal to or higher than 3, and a hydride of silicon represented by a formula SiₙH₂ₙ, wherein n is a natural number equal to or higher than 3. Here, the hydride of silicon represented by the formula SiₘH₂ₘ₊₂, wherein m is a natural number equal to or higher than 3, may be a gas including at least one of trisilane (Si₃H₈), tetrasilane (Si₄ H₁₀) pentasilane (Si₅H₁₂), hexasilane (Si₆H₁₄), and heptasilane (Si₇H₁₆), and the hydride of silicon represented by the formula SiₙH₂ₙ, wherein n is a natural number equal to or higher than 3 may be a gas including at least one of cyclotrisilane (Si₃H₆), cyclotetrasilane (Si₄H₆), cyclopentasilane (Si₅H₁₀), cyclohexasilane (Si₆H₁₂), and cycloheptasilane (Si₇H₁₄).

Alternatively, a chlorosilane-based gas may be used as the seed layer raw material gas instead of the aminosilane-based gas.

Examples of the chlorosilane-based gas include a hydride of silicon represented by the formula SiₘH₂ₘ₊₂, wherein m is a natural number equal to or higher than 1 and at least one of the hydrogen atoms is substituted by a chlorine atom. Detailed examples of the chlorosilane-based gas include gases including at least one of monochlorosilane (SiH₃Cl), dichlorosilane (SiH₂Cl₂), dichlorodisilane (Si₂H₄Cl₂), tetrachlorodisilane (Si₂H₂Cl₄), hexachlorodisilane (Si₂Cl₆), and octachlorotrisilane (Si₃Cl₈).

Alternatively, the chlorosilane-based gas may be a hydride of silicon represented by the formula SiₙH₂ₙ, wherein n is a natural number equal to or higher than 1 and at least one of the hydrogen atoms is substituted by a chlorine atom.

An advantage of using the chlorosilane-based gas is that, for example, carbon contamination that deteriorates insulating properties may be prevented since the chlorosilane-based gas is an inorganic silicon raw material that does not contain carbon like the higher-level silane-based gas.

Also, the chlorosilane-based gas shows a higher seed effect than the higher-level silane-based gas, since the chlorosilane-based gas is able to adsorb silicon atoms to a base at a higher density.

### Modification of Silicon Film Raw Material Gas

An aminosilane-based gas may be used as the silicon film raw material gas, instead of a silane-based gas that does not contain an amino group.

Here, the aminosilane-based gas may be used as the silicon film raw material gas when, for example, the seed layer 2 is formed by using the higher-level silane-based gas equal to or higher than the trisilane.

Also, when the silicon film 3 is formed by using a monosilane (SiH₄) gas as the silicon film raw material gas, a higher-level silane-based gas equal to or higher than the disilane (Si₂H₆) may be used as the seed layer raw material gas.

Alternatively, a chlorosilane-based gas may be used as the silicon film raw material gas.

Like the seed layer raw material gas, an example of the chlorosilane-based gas includes a hydride of silicon represented by the formula SiₘH₂ₙ₊₂, wherein m is a natural number equal to or higher than 1 and at least one of the hydrogen atoms is substituted by a chlorine atom. Detailed examples of the chlorosilane-based gas include gases including at least one of monochlorosilane (SiH₃Cl), dichlorosilane, (SiH₂Cl₂). dichlorodisilane (Si₂H₄Cl₂), tetrachlorodisilane (Si₂H₂Cl₄), hexachlorodisilane (Si₂Cl₆), and octachlorotrisilane (Si₃Cl₆).

Alternatively, the chlorosilane-based gas may be a hydride of silicon represented by the formula SiₙH₂ₙ, wherein n is a natural number equal to or higher than 1 and at least one of the hydrogen atoms is substituted by a chlorine atom.

Like the silane-based gas, the chlorosilane-based gas is an inorganic silicon raw material. Accordingly, carbon contamination in the silicon film 3 may be prevented, and thus the silicon oxide film 4 formed by oxidizing the silicon film 3 may suppress deterioration of insulating properties better than when the silicon film 3 is formed without using an inorganic silicon raw material.

### Suitable Range of Process Temperature when Seed Layer is Formed

A suitable range of a process temperature when a seed layer is formed is from 300° C. to 600° C.

### Suitable Range of Process Pressure when Seed Layer is Formed

A suitable range of a process pressure when a seed layer is formed is from 13.3 Pa (0.1 Torr) to 665 Pa (5 Torr).

### Suitable Range of Flow Rate of Seed Layer Raw Material Gas

A suitable range of a flow rate of a seed layer raw material gas is from 10 sccm to 500 sccm.

### Another Embodiment

In embodiments after the present embodiment, the silicon film 3 is referred to as an amorphous silicon film 3.

The amorphous silicon film 3 includes hydrogen atoms therein. In order to oxidize the amorphous silicon film 3, a temperature of the silicon substrate 1 is increased up to an oxidation temperature in a processing chamber of a semiconductor manufacturing apparatus. During the temperature increase, a bond between the hydrogen atoms and silicon atoms are broken in the amorphous silicon film 3, and thus the hydrogen atoms are separated. In the amorphous silicon film 3 where the hydrogen atoms are separated, the silicon atoms move to regions of the separated hydrogen atoms, i.e., a migration of the silicon atoms occurs. As the migration of the silicon atoms progresses, a surface roughness of the amorphous silicon film 3 deteriorates.

It may be thought that the separation of the hydrogen atoms occurs near the surface of the amorphous silicon film 3, but if the separation of the hydrogen atoms becomes intense or continues for a long period of time, the separation of the hydrogen atoms may occur even in a deep portion of the amorphous silicon film 3. Accordingly, when the migration of the silicon atoms occurs even in the deep portion of the amorphous silicon film 3, not only the surface roughness of the amorphous silicon film 3, but also an interface roughness on an opposite side of the surface of the amorphous silicon film 3, i.e., an interface between the amorphous silicon film 3 and the base, may deteriorate.

In the present embodiment, the deterioration of the surface roughness and the deterioration of the interface roughness of the amorphous silicon film 3 caused by the separation of the hydrogen atoms are suppressed so as to obtain the silicon oxide film 4 having a satisfactory surface roughness and a satisfactory interface roughness.

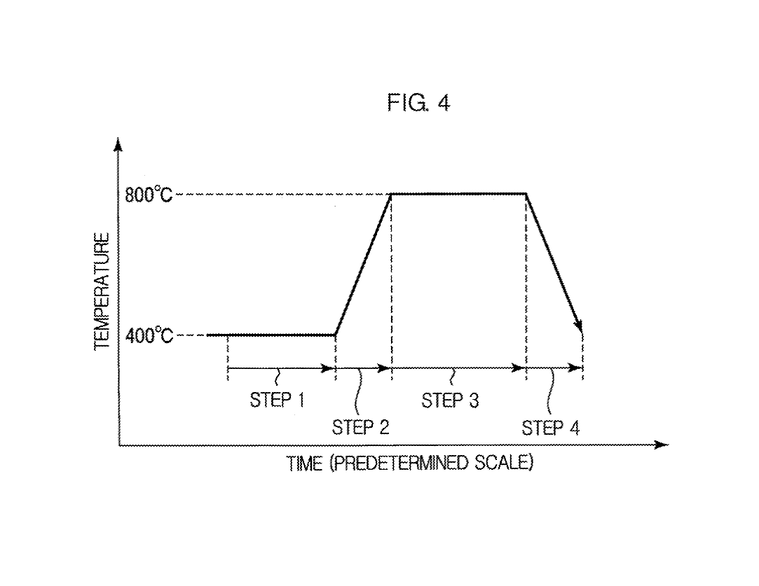

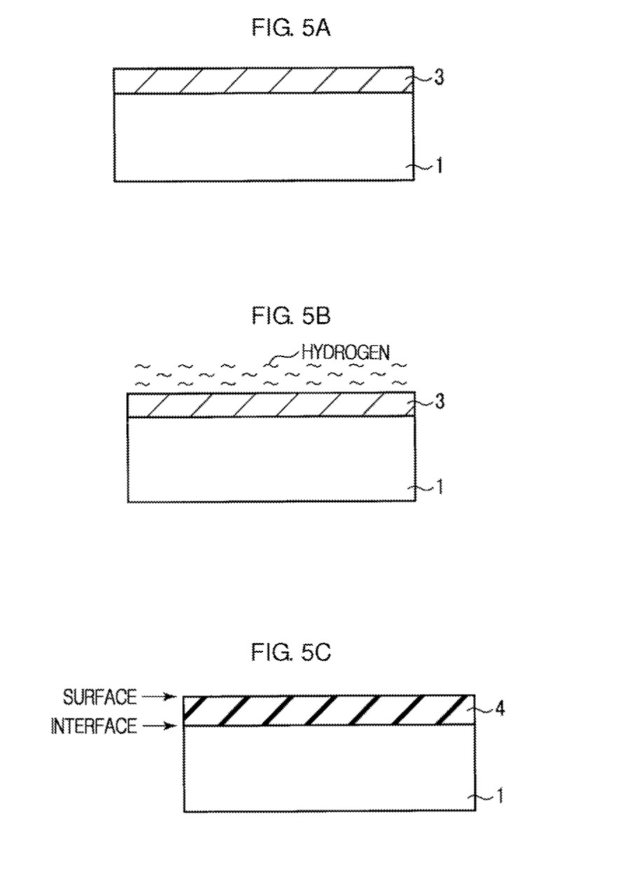

FIG. 4 is a timing chart for describing an example of a method of forming a silicon oxide film, according to the present embodiment. FIGS. 5A through 5C are cross-sectional views for describing main processes of the method of the present embodiment.

As shown in step 1 of FIG. 4 and FIG. 5A, the amorphous silicon film 3 is formed on a base. In the present embodiment, the silicon substrate 1 (silicon wafer silicon single crystal) is also used as the base.

Then, as shown in step 2 of FIG. 4 and FIG. 5B, the temperature of the silicon substrate 1 on which the amorphous silicon film 3 is formed is increased up to an oxidation temperature while supplying hydrogen to the amorphous silicon film 3.

An example of process conditions when the temperature of the silicon substrate 1 is increased up to the oxidation temperature while supplying hydrogen to the amorphous silicon film 3 is as follows:

Hydrogen Flow Rate: 2000 sccm

Process Time: 80 min

Process Temperature: increase from 400° C. to 800° C. (oxidation temperature)

Rate of Temperature Increase: 5° C./min

Process Pressure: 133.3 Pa (1 Torr)

Then, as shown in step 3 of FIG. 4 and FIG. 5C, the amorphous silicon film 3 to which hydrogen is supplied is oxidized at the oxidation temperature to form the silicon oxide film 4 on the silicon substrate 1. Process conditions when forming the silicon oxide film 4 may be identical to the embodiment of FIG. 1. After the oxidizing is completed, as shown in step 4 of FIG. 4, the temperature of the silicon substrate 1 is decreased to a transfer temperature.

According to the method of the present embodiment, as a post-process after forming the amorphous silicon film 3, the temperature of the silicon substrate 1 on which the amorphous silicon film 3 is formed is increased up to the oxidation temperature while supplying hydrogen to the amorphous silicon film 3. Accordingly, while the temperature is increased up to the oxidation temperature, hydrogen is supplied to the amorphous silicon film 3. Thus, an amount of hydrogen separated from the amorphous silicon film 3 may be reduced compared to when hydrogen is not supplied during the temperature increase. Since an amount of hydrogen separated from the amorphous silicon film 3 is reduced, the deterioration of the surface roughness and the deterioration of the interface roughness of the amorphous silicon film 3 caused by the separation of hydrogen may be suppressed.

Accordingly, even in the present embodiment, the silicon oxide film 4 having a satisfactory surface roughness may be obtained. Moreover, in the present embodiment, the silicon oxide film 4 having a satisfactory interface roughness may be obtained.

Also, the present embodiment may be solely performed. However, it is better to form the amorphous silicon film 3 according to the embodiment of FIG. 1 since the amorphous silicon film 3 having a satisfactory surface roughness may be obtained.

As such, when the embodiment of FIG. 1 is combined with the present embodiment, a satisfactory surface roughness of the amorphous silicon film 3 may be maintained even during the temperature increase up to the oxidation temperature, and thus the silicon oxide film 4 having both a satisfactory surface roughness and a satisfactory interface roughness may be obtained.

### Another Embodiment

When the silicon oxide film 4 is formed by oxidizing the amorphous silicon film 3, of course, it is possible to oxidize the amorphous silicon film 3 at room temperature. However, considering practicality, such as maintaining or improving of throughput, it is preferable to increase the temperature of the silicon substrate 1 on which the amorphous silicon film 3 is formed up to the oxidation temperature for oxidation.

However, when the temperature of the silicon substrate 1 on which the amorphous silicon film 3 is formed is increased up to the oxidation temperature, for example, 800° C., the amorphous silicon film 3 is crystallized, and thus the amorphous silicon film 3 changes into a poly crystal silicon film. Looking at the poly crystal silicon film microscopically, the sizes, orientations, and shapes of crystal grains are different from each other. Thus, it is difficult to say that a surface roughness of a silicon film obtained as the amorphous silicon film 3 is crystallized is definitely better than a surface roughness of the amorphous silicon film 3 before crystallization.

Also, the crystallization does not only occur on the surface of the amorphous silicon film 3, but also throughout the amorphous silicon film 3, including the inside of the amorphous silicon film 3. Thus, an interface roughness of an opposite side of the surface of the amorphous silicon film 3, i.e., an interface between the amorphous silicon film 3 and the base deteriorates.

Also, a plurality of dislocations exist in a crystallized silicon film, and the locations of the dislocations are random. An oxidizing agent used for oxidation, for example, easily passes through regions of dislocation than other regions. In other words, the oxidizing agent reaches the base by passing through the random regions of dislocation. When the base is the silicon substrate 1, the oxidizing agent that passed through the regions of dislocation randomly oxidizes the surface of the silicon substrate 1. Such a random oxidation on the surface of the silicon substrate 1 promotes deterioration of an interface roughness.

In the present embodiment, the deterioration of a surface roughness and the deterioration of an interface roughness caused by the crystallization of the amorphous silicon film 3 are suppressed, so as to obtain the silicon oxide film 4 having a satisfactory surface roughness and a satisfactory interface roughness.

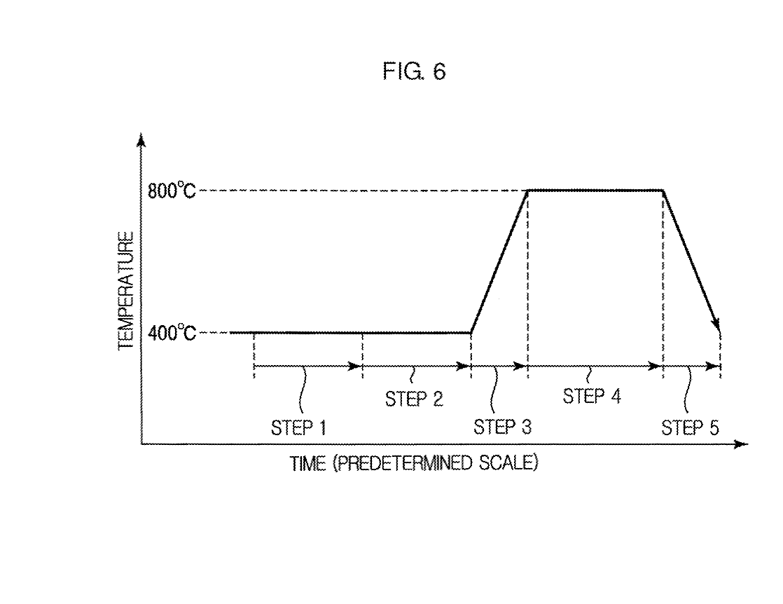

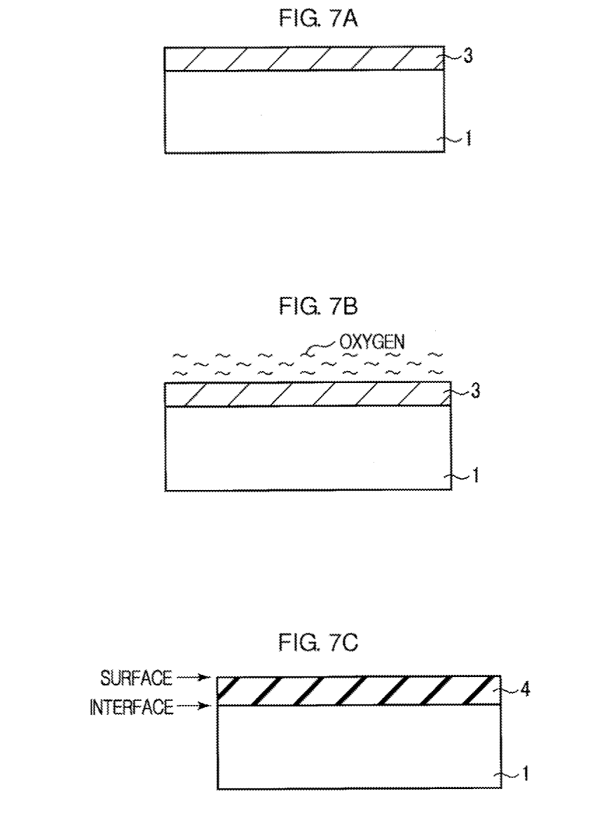

FIG. 6 is a timing chart for describing an example of a method of forming a silicon oxide film, according to the present embodiment, and FIGS. 7A through 7C are cross-sectional views for describing main processes of the method of the present embodiment.

As shown in step 1 of FIG. 6 and FIG. 7A, the amorphous silicon film 3 is formed on a base. In the present embodiment, the silicon substrate 1 (silicon wafer silicon single crystal) is also used as the base.

Then, as shown in step 2 of FIG. 6 and FIG. 7B, the amorphous silicon film 3 is processed under an atmosphere containing oxygen. Accordingly, oxygen is diffused inside the amorphous silicon film 3. As a result of the oxygen being diffused inside the amorphous silicon film 3, a crystallization temperature for crystallizing the amorphous silicon film 3 is increased. As the crystallization temperature is increased, a crystallization suppress process is performed on the amorphous silicon film 3.

An example of process conditions when the amorphous silicon film 3 is processed under the atmosphere containing oxygen is as follows:

Oxygen Source: O₂

Oxygen Source Flow Rate: 5000 sccm

Process Time: 5 to 60 min

Process Temperature: 400° C.

Process Pressure: 133.3 Pa (1 Torr)

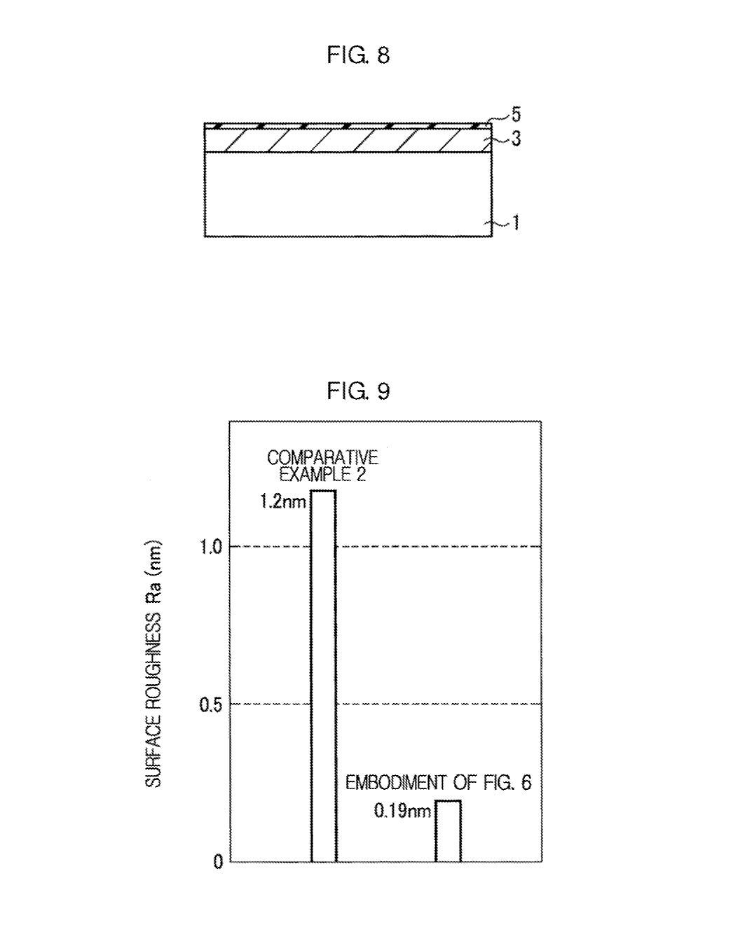

Alternatively, as shown in FIG. 8, a film 5 of silicon oxide may be formed by thinly oxidizing the surface of the amorphous silicon film 3 when the amorphous silicon film 3 is processed under the atmosphere containing oxygen. The film 5 of silicon oxide operates as a hydrogen separation suppression film for suppressing “separation of hydrogen atoms” described in the embodiment of FIG. 4. As such, when the film 5 of silicon oxide is formed on the surface of the amorphous silicon film 3, the separation of hydrogen atoms during the temperature increase up to the oxidation temperature performed afterwards may be suppressed. Accordingly, the crystallization is suppressed while the deterioration of a surface roughness and the deterioration of an interface roughness of the amorphous silicon film 3 caused by the separation of hydrogen atoms are suppressed.

An example of process conditions when the film 5 of silicon oxide is formed on the surface of the amorphous silicon film 3 is as follows:

Oxygen Source: At least one of O₂, O₂/H₂, and O₃

Oxygen Source Flow Rate: 1 to 10 slm

Process Time: 5 to 60 min

Process Temperature: 400° C.

Process Pressure: 133.3 Pa (1 Torr)

Then, as shown in step 3 of FIG. 6, the temperature of the silicon substrate 1 on which the amorphous silicon film 3 on which the crystallization suppression process is performed is formed is increased up to the oxidation temperature.

Then, as shown in step 4 of FIG. 6 and FIG. 7C, the amorphous silicon film 3 on which the crystallization suppression process is performed is oxidized to form the silicon oxide film 4 on the silicon substrate 1. Process conditions when forming the silicon oxide film 4 may be identical to the embodiment of FIG. 1. After the oxidizing is completed, as shown in step 5 of FIG. 6, the temperature of the silicon substrate 1 is decreased to the transfer temperature.

According to the method of the present embodiment, the amorphous silicon film 3 is processed under the atmosphere containing oxygen as a post-process after forming the amorphous silicon film 3. Accordingly, oxygen may is diffused inside the amorphous silicon film 3. Thus, the crystallization suppression process is performed on the amorphous silicon film 3 as the crystallization temperature of the amorphous silicon film 3 is increased. By performing the crystallization suppression process on the amorphous silicon film 3, the deterioration of a surface roughness and the deterioration of an interface roughness caused by the crystallization of the amorphous silicon film 3 may be suppressed.

Accordingly, in the present embodiment, the silicon oxide film 3 having both a so satisfactory surface roughness and a satisfactory interface roughness may be obtained.

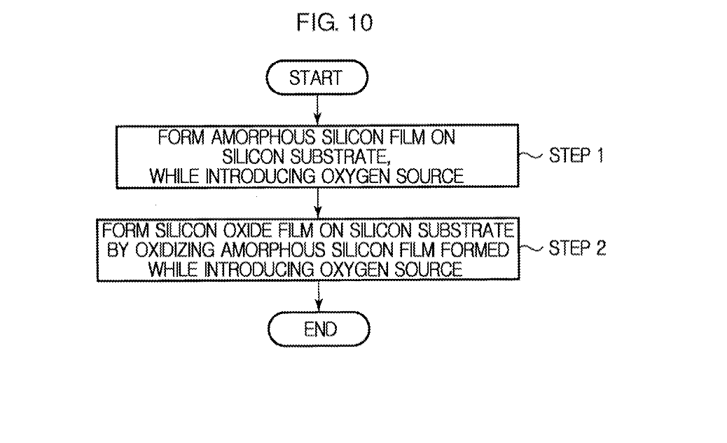

A surface roughness Ra of the silicon oxide film 4 formed according to an example of the present embodiment (existence of the film 5) is measured and compared with a surface roughness Ra of a silicon oxide film formed when a process under an oxygen atmosphere is not performed (Comparative Example 2). A result of the comparison is shown in FIG. 9.

As shown in FIG. 9, the surface roughness Ra of the silicon oxide film of Comparative Example 2 was “Ra=1.2 nm” whereas the surface roughness Ra of the silicon oxide film 4 formed according to the example of the present embodiment was “Ra=0.19 nm”,

Also, a method of measuring the surface roughness Ra is identical to that described with reference to FIG. 3 in the embodiment of FIG. 1, and as follows:

Measuring Device: Atomic force microscope (AFM)

Measurement Range: 1 μm×1 μm

Roughness: Mean line roughness (Ra)

As such, according to the method of the present embodiment, the silicon oxide film 4 having a satisfactory surface roughness may be obtained. Also, the satisfactory surface roughness obtained as the result of the example of the present embodiment may be a result of suppressing crystallization of the amorphous silicon film 3. Accordingly, by suppressing the crystallization of the amorphous silicon film 3, an interface roughness may be satisfactory.

Also, like the embodiment of FIG. 4, the present embodiment may be solely performed. However, it is better to form the amorphous silicon film 3 according to an example of the embodiment of FIG. 1 since the amorphous silicon film 3 having a satisfactory surface roughness may be obtained.

Alternatively, the present embodiment may be combined with the embodiment of FIG. 4. When the present embodiment is combined with the embodiment of FIG. 4, the crystallization of the amorphous silicon film 3 may be suppressed while suppressing hydrogen separation from the amorphous silicon film 3. When the embodiment of FIG. 4 is combined with the present embodiment, for example, the film 5 of silicon oxide may not be necessarily formed on the surface of the amorphous silicon film 3, as shown in FIG. 8. However, after forming the film 5 of silicon oxide on the surface of the amorphous silicon film 3, additionally, hydrogen may be supplied while increasing the temperature of the silicon substrate 1 on which the amorphous silicon film 3 is formed up to the oxidation temperature. At this time, the deterioration of a surface roughness and the deterioration of an interface roughness caused by separation of hydrogen may be further effectively suppressed due to the film 5 and the supply of hydrogen.

Of course, it is possible to combine both the embodiments of FIGS. 1 and 4 with the present embodiment.

### Another Embodiment

Like the embodiment of FIG. 6, the present embodiment is about suppressing the deterioration of a surface roughness and the deterioration of an interface roughness caused by the crystallization of the amorphous silicon film 3.

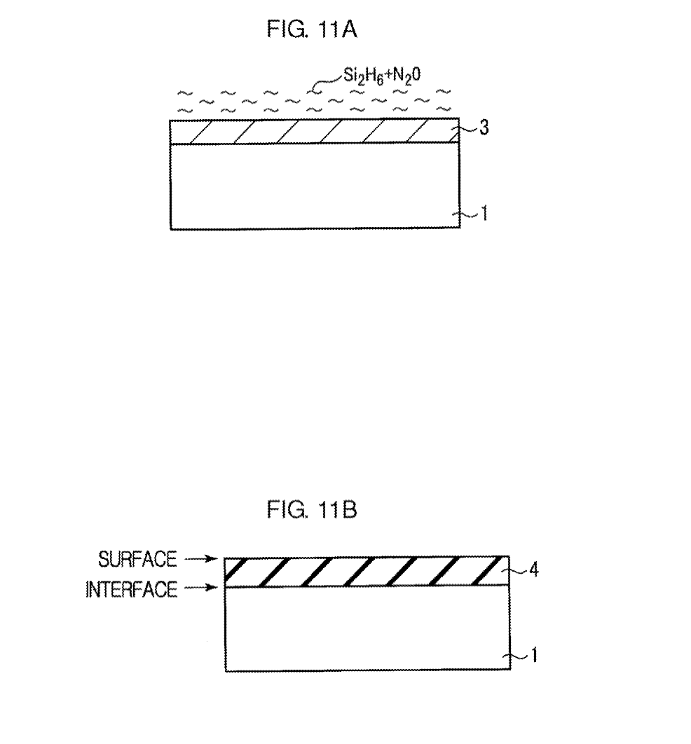

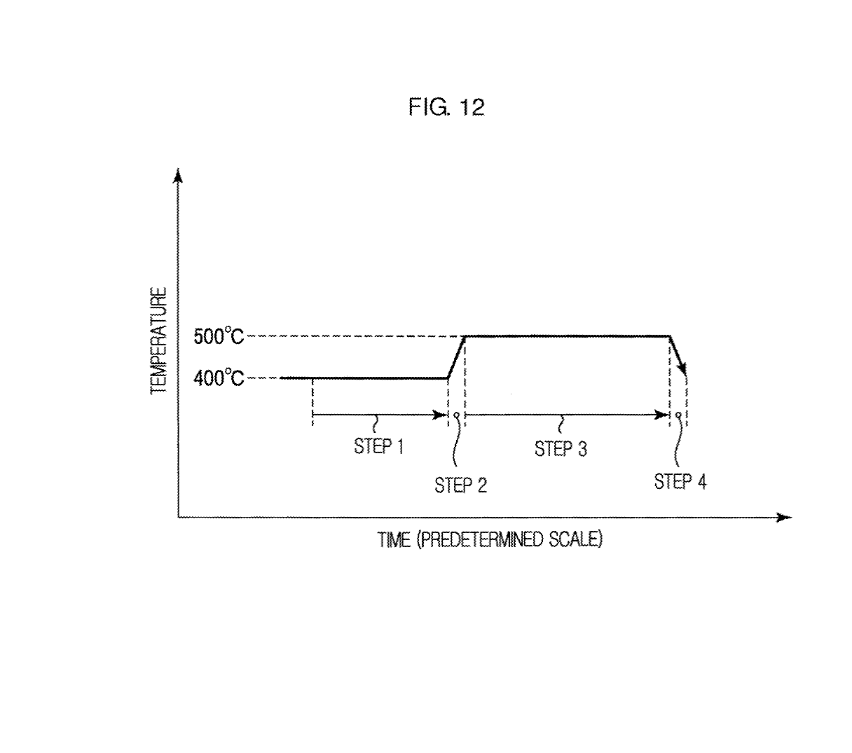

FIG. 10 is a flowchart showing an example of a method of forming a silicon oxide film, according to the present embodiment, and FIGS. 11A and 11B are cross-sectional views for describing main processes of the method of the present embodiment.

As shown in step 1 of FIG. 10 and FIG. 11A, the amorphous silicon film 3 is formed on a base, in the present embodiment, on the silicon substrate 1, while introducing an oxygen source, for example, a N₂O gas, with a silicon raw material gas.

An example of process conditions when the amorphous silicon film 3 is formed while introducing the oxygen source is as follows:

Silicon Raw Material: Si₂H₈

Silicon Raw Material Flow Rate: 200 sccm

Oxygen Source: N₂O

Oxygen Source Flow Rate: 10 sccm

Process Time: 6 min

Process Temperature: 400° C.

Process Pressure: 133.3 Pa (1 Torr)

Then, as shown in step 2 of FIG. 10 and FIG. 11B, the amorphous silicon film 3 formed while introducing the oxygen source is oxidized to form the silicon oxide film 4 on the silicon substrate 1.

According to the method of the present embodiment, since the oxygen source is introduced while forming the amorphous silicon film 3, the amorphous silicon film 3 is an oxygen-doped amorphous silicon film 3. The oxygen-doped amorphous silicon film 3, as described in the embodiment of FIG. 6, has a higher crystallization temperature than an oxygen-undoped amorphous silicon film. Accordingly, like the embodiment of FIG. 6, the deterioration of the surface roughness and the deterioration of the interface roughness caused by the crystallization of the amorphous silicon film 3 may be suppressed, and thus the silicon oxide film 4 having both a satisfactory surface roughness and a satisfactory interface roughness may be obtained.

Also, the present embodiment may be combined with the embodiment of FIG. 1, with the embodiment of FIG. 4, or with both the embodiments of FIGS. 1 and 4.

### Another Embodiment

Like the embodiments of FIGS. 6 and 10, the present embodiment is about suppressing the deterioration of a surface roughness and the deterioration of an interface roughness caused by the crystallization of the amorphous silicon film 3.

### An Example

FIG. 12 is a timing chart for describing an example of a method of forming a silicon oxide film, according to the present embodiment.

As shown in step 1 of FIG. 12, the amorphous silicon film 3 is formed on a base, in the present example, on the silicon substrate 1.

Then, as shown in step 2, the temperature of the silicon substrate 1 on which the amorphous silicon film 3 is formed is increased up to the oxidation temperature.

In the present example, the oxidation temperature is lower than the crystallization temperature for crystallizing the amorphous silicon film 3. For example, in the present example, the oxidation temperature is 500° C.

Then, as shown in step 3, the amorphous silicon film 3 formed on the silicon substrate 1 is oxidized at the temperature lower than the crystallization temperature, for example, at 500° C., so as to form the silicon oxide film 4 on the silicon substrate 1.

An example of process conditions when the silicon oxide film 4 is formed in the present example is as follows:

Oxidation Method: Depressurization-radical oxidation method

Oxidizing agent: O₂/H₂

Oxidation Time: 100 min

Oxidation Temperature: 500° C.

Process Pressure: 133 Pa (1 Torr)

When the oxidizing is completed, as shown in step 4, the temperature of the silicon substrate 1 is decreased to the transfer temperature.

According to the present embodiment, since the amorphous silicon film 3 is oxidized at the temperature lower than the crystallization temperature, the amorphous silicon film 3, for example, does not change into a poly crystal silicon film. Accordingly, like the embodiments of FIGS. 6 and 10, the deterioration of a surface roughness and the deterioration of an interface roughness caused by the crystallization of the amorphous silicon film 3 may be suppressed, and thus the silicon oxide film 4 having both a satisfactory surface roughness and a satisfactory interface roughness may be obtained.

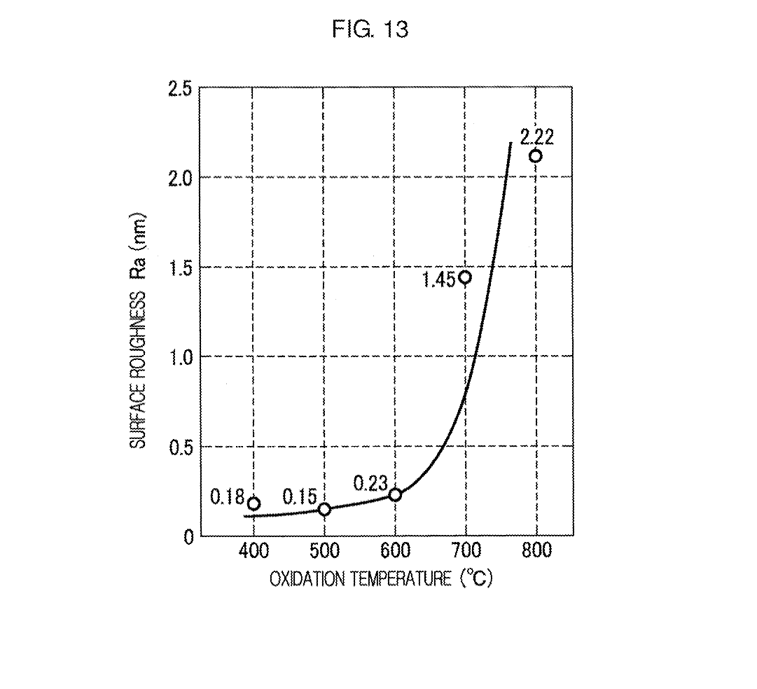

FIG. 13 is a diagram for describing a relationship between the oxidation temperature and surface roughness Ra of the silicon oxide film 4.

As shown in FIG. 13, when the oxidation temperature is lower than or equal to 600° C., the surface roughness Ra of the silicon oxide film 4 is “Ra=0.23 nm (600° C.)”, “Ra=0.15 nm (500° C)”, and “Ra=0.18 nm (400° C.)”. In this regard, when the oxidation temperature is equal to or higher than 700° C., the surface roughness Ra is “Ra=1.45 nm (700° C.)” and “Ra=2.22 nm (800° C.)”.

Also, a process pressure during oxidation is unified to 133 Pa in all the samples, and a type of an oxidizing agent, a flow rate of the oxidizing agent, and an oxidation time are fixed in all the samples. Only the oxidation temperature is changed.

Also, a method of measuring the surface roughness Ra is identical to that of FIG. 3 of the embodiment of FIG. 1 and FIG. 9 of the embodiment of FIG. 6, and is as follows:

Measuring Device: Atomic force microscope (AFM)

Measurement Range: 1 μm×1 μm

Roughness: Mean line roughness (Ra)

As such, there is a correlation between the oxidation temperature and the surface roughness Ra of the silicon oxide film 4. This may be dependent upon whether the amorphous silicon film 3 is crystallized or not.

In other words, when the oxidation temperature is suppressed to 600° C. or lower, the oxidation temperature is lower than the crystallization temperature of the amorphous silicon film 3, and thus a satisfactory surface roughness may be maintained. Also, since the amorphous silicon film 3 is oxidized at the temperature lower than the crystallization temperature, the deterioration of an interface roughness caused by the crystallization of the amorphous silicon film 3 may be suppressed.

It is assumed that the crystallization temperature of the amorphous silicon film 3 is between 600° C. and 700° C. as understood form the result shown in FIG. 13 when the process pressure is 133 Pa.

Accordingly, an upper limit of the oxidation temperature is 600° C. or lower in regards to suppressing the oxidation temperature to be lower than the crystallization temperature. Also, a lower limit of the oxidation temperature is room temperature or above since oxidation is possible at room temperature. In the present specification, the room temperature is 25° C. Also, considering maintaining and improving of throughput, it is practically preferable that the lower limit of the oxidation temperature is 300° C. or above.

### Another Example

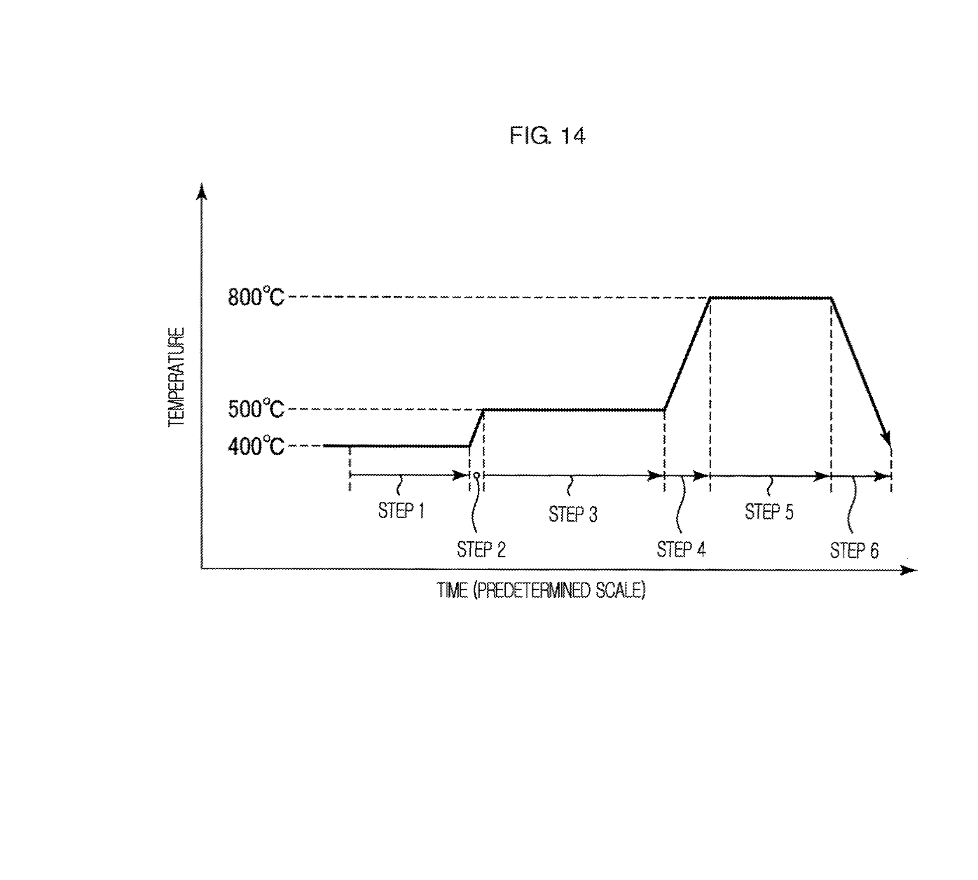

FIG. 14 is a timing chart for describing another example of the method of the present embodiment.

As shown in steps 1 through 3 of FIG. 14, like the previous example described with reference to FIG. 12, the amorphous silicon film 3 formed on the silicon substrate 1 is oxidized at a temperature lower than the crystallization temperature for crystallizing the amorphous silicon film 3, for example, at 500° C., so as to form the silicon oxide film 4 on the silicon substrate 1.

In the present example, after oxidizing at the temperature lower than the crystallization temperature, as shown in step 4 of FIG. 14, a temperature of the amorphous silicon film 3 oxidized at the temperature lower than the crystallization temperature is increased to a temperature equal to or higher than the crystallization temperature. Additionally, as shown in step 5, the silicon oxide film 4 is re-oxidized at the temperature equal to or higher than the crystallization temperature. After the re-oxidizing is completed, as shown in step 6, the temperature of the silicon substrate 1 is decreased to the transfer temperature.

As such, after forming the silicon oxide film 4 by oxidizing the amorphous silicon film 3 at the temperature lower than the crystallization temperature, the silicon oxide film 4 oxidized at the temperature lower than the crystallization temperature may be re-oxidized at the temperature equal to or higher than the crystallization temperature.

Since the silicon oxide film 4 is formed by oxidizing the amorphous silicon film 3 at the temperature lower than the crystallization temperature in the present example, the deterioration of a surface roughness and the deterioration of an interface roughness caused by the crystallization of the amorphous silicon film 3 may be suppressed like the previous example, and thus the silicon oxide film 4 having both a satisfactory surface roughness and a satisfactory interface roughness may be obtained.

Also, in the present example, since the silicon oxide film 4 oxidized at the temperature lower than the crystallization temperature is re-oxidized at the temperature equal to or higher than the crystallization temperature, a film quality of the silicon oxide film 4, for example, may be denser compared to the previous example where the silicon oxide film 4 is not re-oxidized. When the silicon oxide film 4 is denser, for example, the silicon oxide film 4 may have excellent electric characteristics of a low leak current and a high-pressure resistance.

Also, the crystallization temperature of the amorphous silicon film 3 is between 600° C. and 700° C. when the process pressure is 133 Pa, as shown in FIG. 13. Accordingly, the re-oxidizing is performed at a temperature higher than 600° C. Also, an upper limit of a re-oxidation temperature is logically lower than a melting point of the base, in the present example, lower than a melting point of the silicon substrate 1. Since the melting point of the silicon substrate 1 is about 1410° C. at room temperature and room pressure, the re-oxidizing may be performed at a temperature lower than about 1410° C. under room temperature and room pressure. However, in terms of practicality considering a thermal history, the upper limit of the re-oxidization temperature may be equal to or lower than 800° C.

However, the present example does not deny the silicon oxide film 4 formed according to the method of the previous example. If electric characteristics of the silicon oxide film 4 formed according to the method of the previous example, for example, the electric characteristics required by a thin film of a semiconductor integrated circuit apparatus is sufficiently satisfied, the silicon oxide film 4 formed according to the method of the previous example may be obviously employed as a thin film of a semiconductor integrated circuit apparatus.

Also, both the previous and present examples of the present embodiment may be combined with any one of the embodiments of FIGS. 1, 4, 6 and 10.

### Another Embodiment

In the embodiments of FIGS. 6, 10, 12 and 14, the deterioration of a surface roughness and the deterioration of an interface roughness caused by the crystallization of the amorphous silicon film 3 are suppressed by using a chemical method.

In the present embodiment, the deterioration of an interface roughness caused by the crystallization of the amorphous silicon film 3 is specifically suppressed by using a physical method.

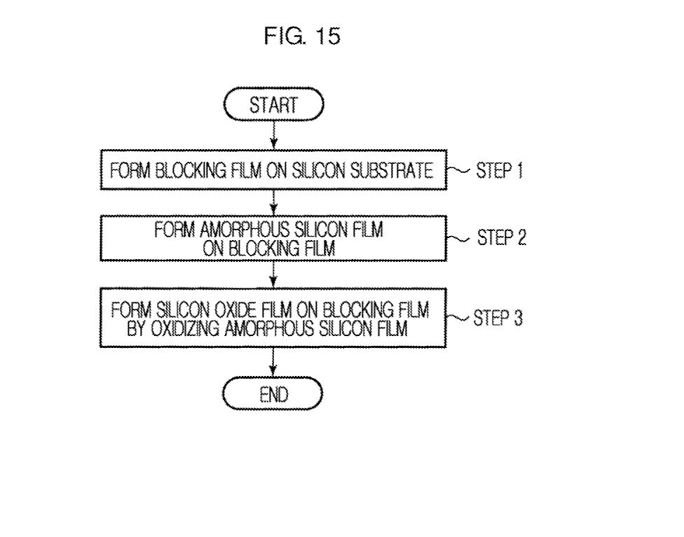

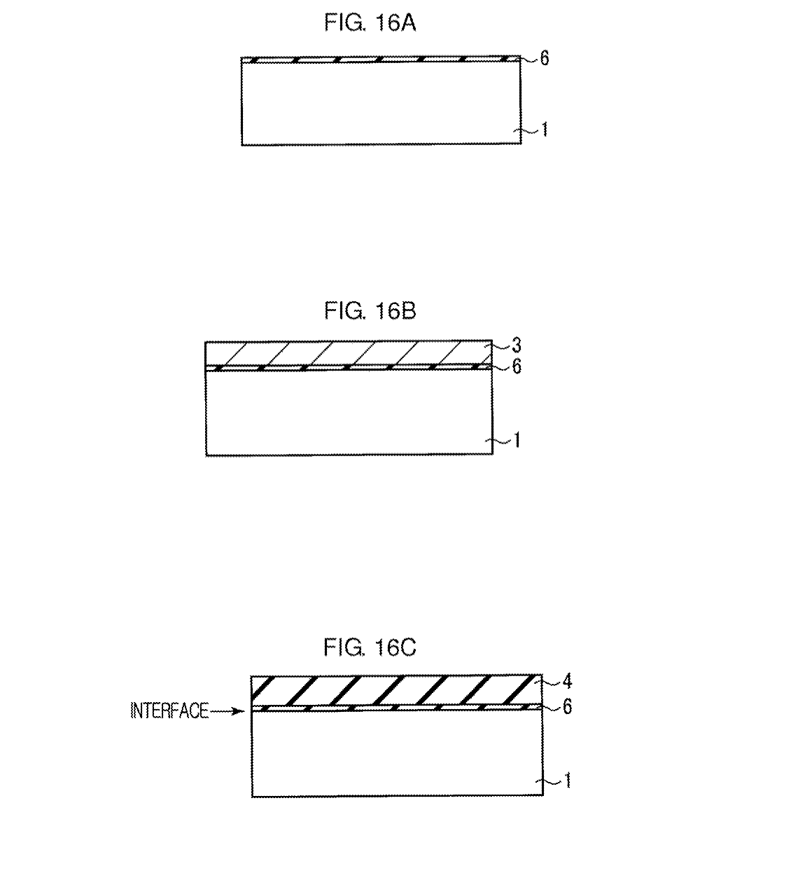

FIG. 15 is a flowchart showing an example of a method of forming a silicon oxide film, according to the present embodiment, and FIGS. 16A through 16C are cross-sectional views for describing main processes of the method of the present embodiment.

As shown in step 1 of FIG. 15 and FIG. 16A, a blocking film 6, which blocks progression of a crystal growth, is formed on a base, in the present embodiment, on the silicon substrate 1. The blocking film 6 may be a film capable of blocking the silicon substrate 1 from growing as crystals penetrate into the silicon substrate 1 when an amorphous silicon film formed afterwards is crystallized. Examples of the blocking film 6 include a film including at least one of a silicon oxide film, a silicon nitride film, and a metal oxide film. The silicon oxide film may be formed by directly oxidizing the silicon substrate 1. For example, the silicon oxide film may be a thermal oxide film, a radical oxide film, or the like. Likewise, the silicon nitride film may be formed by directly nitrating the silicon substrate 1. For example, the silicon nitride film may be a thermal nitride film or a radical nitride film. The metal oxide film may be, for example, a tungsten oxide film, an alumina film, a titania film, or the like.

In the present embodiment, a radical oxide film formed by directly radical-oxidizing the silicon substrate 1 is used as the blocking film 6.

An example of process conditions when the blocking film 6 is formed is as follows:

Oxidation Method: Depressurization-radical oxidation method

Oxidizing agent: O₂/H₂

Oxidation Time: 15 min

Oxidation Temperature: 400° C.

Process Pressure: 133.3 Pa (1 Torr)

Then, as shown in step 2 of FIG. 15 and FIG. 16B, the amorphous silicon film 3 is formed on the blocking film 6.

Then, as shown in step 3 of FIG. 15 and FIG. 16C, the silicon oxide film 4 is formed on the blocking film 6 by oxidizing the amorphous silicon film 3.

According to the method of the present embodiment, the blocking film 6 for blocking the progression of the crystal growth is formed on the silicon substrate 1, as a pre-process before forming the amorphous silicon film 3. Accordingly, even when the amorphous silicon film 3 is crystallized and changed into a poly crystal silicon film while oxidizing the amorphous silicon film 3, crystals in the poly crystal silicon film may be suppressed from growing and penetrating into the silicon substrate 1. Thus, the deterioration of an interface roughness caused by the crystallization of the amorphous silicon film 3 may be specifically suppressed.

Also, the present embodiment may be combined with any of the embodiments of FIGS. 1. 4, 6. 10, 12 and 14.

While this invention has been particularly shown and described with reference to exemplary embodiments thereof, it will be understood by one of ordinary skill in the art that various changes in form and details may be made therein without departing from the spirit and scope of the invention as defined by the appended claims.

For example, the process conditions are exemplified in detail in the above embodiments, but the process conditions are not limited to those of the examples.

Also, the silicon substrate 1 is used as the base, but the base is not limited to the silicon substrate 1. For example, the base may be a silicon nitride film or a poly crystal silicon film. Of course, the base may be a metal film forming an inner wire layer, such as tungsten or copper. Alternatively, the base may be a dielectric film having a high relative dielectric constant than a silicon oxide film, such as a tantalum oxide film, used as a dielectric film of a capacitor or the like.

Also, the depressurization-radical oxidation method is used as an oxidation method when forming the silicon oxide film 4, specifically as a preferable oxidation method, but the oxidation method is not limited to a radical oxidation method. As the oxidation method, for example, thermal oxidation, ozone oxidation using ozone as an oxidizing agent, plasma oxidation plasmatizing an oxidizing agent, or wet oxidation using steam as an oxidizing agent may be used.

Also, regarding oxidation in a thickness direction, all of the silicon film 3 or the amorphous silicon film 3, and the seed layer 2 may be oxidized so that there is no silicon left.

Also, when the base is formed of a material that is easily oxidized, such as the silicon substrate 1, it is possible to, as occasion demands, completely oxidize all of the silicon film 3 or the amorphous silicon film 3, and the seed layer 2, and progress the oxidation to the base, for example, to the silicon substrate 1. Even when the oxidation is progressed to the base as such, an interface roughness may be satisfactory.

Also, the aminosilane-based gas is not limited to that in which the number of silicon (Si) atoms in a molecular formula is one, and may be, for example, hexakisethylaminodisilane (C₁₂H₃₆N₆Si₂) in which the number of silicon atoms in the molecular formula is two.

Alternatively, aside from hexakisethylaminodisilane, the aminosilane-based gas may use any one of the materials represented by Formulas 1 through 4 below.

((R1R2)N)ₙSi₂H₆₋ₙ₋ₘ(R3)ₘ . . . n: number of amino groups, m: number of alkyl groups (1

((R1)NH)ₙSi₂H₆₋ₙ₋ₘ(R3)ₘ . . . n: number of amino groups, m: number of alkyl groups (2)

In Formulas (1) and (2), R1, R2, and R3 are each equal to one of CH, C₂H₆, and C₃H₇, and R1, R2, and R3 may or may not be equal. Also, n is an integer from 1 to 6 and m is 0 or an integer from 1 to 5.

((R1R2)N)Si₂H₆₋ₙ₋ₘ(Cl)ₘ . . . n: number of amino groups, m: number of chlorines (3)

((R1)NH)ₙSi₂H₆₋ₙ₋ₘ(Cl)ₘ . . . n: number of amino groups, m: number of chlorines (4)

In Formulas (3) and (4), R1 and R2 are each equal to one of CH₃, C₂H₅, and C₃H₇, and R1 and R2 may or may not be equal. Also, n is an integer from 1 to 6 and m is 0 or an integer from 1 to 5.

Alternatively, the present invention may be variously modified within a range that does not deviate from the scope of the invention.

According to the present invention, the method of forming a silicon oxide film, which is capable of obtaining a silicon oxide film having a satisfactory surface roughness, a satisfactory interface roughness, or both the satisfactory surface roughness and the satisfactory interface roughness, can be provided.

What is claimed is:

1. A method of forming a silicon oxide film, the method comprising:
forming a seed layer on a base;
forming a silicon film on the seed layer; and
forming the silicon oxide film on the base by oxidizing the silicon film and the seed layer.

2. The method of claim 1, wherein the seed layer is formed by adsorbing an aminosilane-based gas, a higher-level silane-based gas equal to or higher than a trisilane, or a chlorosilane-based gas on the base, and
the silicon film is formed by supplying a lower-level silane-based gas lower than or equal to a disilane, an aminosilane-based gas, or a chlorosilane-based gas on the seed layer.

3. The method of claim 2, wherein the aminosilane-based gas is selected from gases comprising at least one of butylaminosilane (BAS), bistertiarybutylaminosilane (BTBAS), dimethylaminosilane (DMAS). bisdimethylaminosilane (BDMAS), tridimethylaminosilane (TDMAS), diethylaminosilane (DEAS), bisdiethylaminosilane (BDEAS), dipropylaminosilane (DPAS), diisopropylaminosilane (DIPAS), hexakisethylaminodisilane, Formula 1; ((R1R2)N)ₙSi₂H₆₋ₙ₋ₘ(R3)ₘ, Formula 2; ((R1)NH)ₙSi₂H₆₋ₙ₋ₘ(R3)ₘ, Formula 3; ((R1R2)N)ₙSi₂H₆₋ₙ₋ₘ(Cl)ₘ, and Formula 4; ((R1)NH)ₙSi₂H₆₋ₙ₋ₘ(Cl)ₘ, wherein in Formulas 1 and 2, n denotes the number of amino groups and m denotes the number of alkyl groups, in Formulas 3 and 4, n denotes the number of amino groups and m denotes the number of chlorines, and in Formulas 1 through 4, n is an integer from 1 to 6, m is 0 or an integer from 1 to 5, R1, R2, and R3 are each equal to one of CH₃, C₂H₅, and C₃H₇, and R1, R2 and R3 are or are not equal.

4. The method of claim 2, wherein the higher-level silane-based gas equal to or higher than the trisilane is a hydride of silicon represented by a formula SiₘH₂ₘ₊₂, wherein m is a natural number equal to or higher than 3, or a hydride of silicon represented by a formula SiₙH₂ₙ, wherein n is a natural number equal to or higher than 3.

5. The method of claim 4, wherein the hydride of silicon represented by the formula SiₘH₂ₘ₊₂, wherein m is a natural number equal to or higher than 3, is selected from gases comprising at least one of trisilane (Si₃H₈), tetrasilane (Si₄H₁₀). pentasilane (Si₅H₁₂), hexasilane (Si₆H₁₄), and heptasilane (Si₇H₁₆), and
the hydride of silicon represented by the formula SiₙH₂ₙ, wherein n is a natural number equal to or higher than 3, is selected from gases comprising at least one of cyclotrisilane (Si₃H₆), cyclotetrasilane, (Si₄H₈), cyclopentasilane (Si₅H₁₀), cyclohexasilane (Si₆H₁₂), and cycloheptasilane (Si₇H₁₄).

6. The method of claim 2, wherein the chlorosilane-based gas is obtained by substituting at least one of the hydrogen atoms of a hydride of silicon represented by a formula SiₘH₂ₘ₊₂, wherein m is a natural number equal to or higher than 1, with a chlorine atom, or by substituting at least one of the hydrogen atoms of a hydride of silicon represented by a formula SiₙH₂ₙ, wherein n is a natural number equal to or higher than 1, with a chlorine atom.

7. The method of claim 6, wherein the chlorosilane-based gas obtained by substituting at least one of the hydrogen atoms of the hydride of silicon represented by the formula SiₘH₂ₘ₊₂, wherein m is a natural number equal to or higher than 1, with a chlorine atom is selected from gases comprising at least one of monochlorosilane (SiH₃Cl), dichlorosilane (SiH₂Cl₂), dichlorodisilane (Si₂H₄Cl₂), tetrachlorodisilane (Si₂H₇Cl₄), hexachlorodisilane (Si₂Cl₆), and octachlorotrisilane (Si₃Cl₈).

8. The method of claim 2, wherein the lower-level silane-based gas lower than or equal to the disilane is selected from gases comprising at least one of monosilane (SiH₄) and disilane (Si₂H₆).

9. A method of forming a silicon oxide film, the method comprising:
forming an amorphous silicon film on a base;
increasing a temperature up to an oxidation temperature while supplying hydrogen to the amorphous silicon film; and
forming the silicon oxide film on the base by oxidizing the amorphous silicon film to which the hydrogen is supplied at the oxidation temperature.

10. A method of forming a silicon oxide film, the method comprising:
forming an amorphous silicon film on a base:
performing a re-crystallization suppressing process on the amorphous silicon film under an atmosphere containing oxygen; and
forming the silicon oxide film on the base by oxidizing the amorphous silicon film on which the re-crystallization suppressing process is performed.

11. A method of forming a silicon oxide film, the method comprising:
forming an amorphous silicon film on a base while introducing oxygen; and
forming the silicon oxide film on the base by oxidizing the amorphous silicon film formed while introducing the oxygen.

12. A method of forming a silicon oxide film, the method comprising:
forming an amorphous silicon film on a base; and
forming the silicon oxide film on the base by oxidizing the amorphous silicon film at a temperature lower than a crystallization temperature of the amorphous silicon film.

13. The method of claim 12, further comprising, after the forming of the silicon oxide film, re-oxidizing the silicon oxide film formed by oxidizing the amorphous silicon film at the temperature lower than the crystallization temperature, at a temperature equal to or higher than the crystallization temperature.

14. The method of claim 13, wherein a re-oxidation temperature in the re-oxidizing is higher than 600° C. and lower than or equal to 800° C.

15. The method of claim 12, wherein an oxidation temperature in the forming of the silicon oxide film is equal to or higher than room temperature and lower than or equal to 600° C.

16. A method of forming a silicon oxide film, the method comprising:
forming a blocking film, which blocks a progression of crystal growth, on a base:
forming an amorphous silicon film on the blocking film; and
forming the silicon oxide film on the blocking film by oxidizing the amorphous silicon film.

17. The method of claim 16, wherein the blocking film is selected from films comprising at least one of a silicon oxide film, a silicon nitride film, and a metal oxide film.

18. The method of claim 9, wherein the amorphous silicon film is formed by forming a seed layer on the base and forming the amorphous silicon film on the seed layer.

19. The method of claim 18, wherein the seed layer is formed by adsorbing is an aminosilane-based gas, a higher-level silane-based gas equal to or higher than a trisilane, or a chlorosilane-based gas on the base, and
the amorphous silicon film is formed by supplying a lower-level saline-based gas lower than or equal to a disilane, an aminosilane-based gas, or a chlorosilane-based gas on the seed layer.

20. The method of claim 19, wherein the aminosilane-based gas is selected from gases comprising at least one of butylaminosilane (BAS), bistertiarybutylaminosilane (BTBAS), dimethylaminosilane (DMAS), bisdimethylaminosilane (BDMAS), tridimethylaminosilane (TDMAS), diethylaminosilane (DEAS), bisdiethylaminosilane (BDEAS), dipropylaminosilane (DPAS), diisopropylaminosilane (DIPAS), hexakisethylaminodisilane, Formula 1; ((R1R2)N)ₙSi₂H₆₋ₙ₋ₘ(R3)ₘ, Formula 2; ((R1)NHₙSi₂H₆₋ₙ₋ₘ(R3)ₘ, Formula 3; ((R1R2)N)ₙSi₂H₆₋ₙ₋ₘ(Cl)ₘ, and Formula 4; ((R1)NH)ₙS₂H₆₋ₙ₋ₘ(Cl)ₘ, wherein in Formulas 1 and 2, n denotes the number of amino groups and m denotes the number of alkyl groups, in Formulas 3 and 4, n denotes the number of amino groups and m denotes the number of chlorines, and in Formulas 1 through 4, n is an integer from 1 to 6, m is 0 or an integer from 1 to 5, R1, R2, and R3 are each equal to one of CH₃, C₂H₅, and C₃H₇, and R1, R2, and R3 are or are not equal.

21. The method of claim 19, wherein the higher-level silane-based gas equal to or higher than the trisilane is a hydride of silicon represented by a formula SiₘH₂ₘ₊₂, wherein m is a natural number equal to or higher than 3, or a hydride of silicon represented by a formula SiₙH₂ₙ, wherein n is a natural number equal to or higher than 3.

22. The method of claim 21, wherein the hydride of silicon represented by the formula SiₘH₂ₘ₊₂, wherein m is a natural number equal to or higher than 3, is selected from gases comprising at least one of trisilane (Si₃H₈), tetrasilane (Si₄H₁₀), pentasilane (Si₅H₁₂), hexasilane (Si₆H₁₄), and heptasilane (Si₇H₁₆), and
the hydride of silicon represented by the formula SiₙH₂ₙ, wherein n is a natural number equal to or higher than 3, is selected from gases comprising at least one of cyclotrisilane (Si₃H₈), cyclotetrasilane, (Si₄H₈), cyclopentasilane (Si₅H₁₀). cyclohexasilane (Si₆H₁₂), and cycloheptasilane (S₇H₁₄).

23. The method of claim 19, wherein the chlorosilane-based gas is obtained by substituting at least one of the hydrogen atoms of a hydride of silicon represented by a formula SiₘH₂ₘ₊₂, wherein m is a natural number equal to or higher than 1, with a chlorine atom, or by substituting at least one of the hydrogen atoms of a hydride of silicon represented by a formula SiₙH₂ₙ, wherein n is a natural number equal to or higher than 1, with a chlorine atom.

24. The method of claim 23, wherein the chlorosilane-based gas obtained by substituting at least one of the hydrogen atoms of the hydride of silicon represented by the formula SiₘH₂ₘ₊₂, wherein m is a natural number equal to or higher than 1, with a chlorine atom is selected from gases comprising at least one of monochlorosilane (SiH₃Cl), dichlorosilane (SiH₂Cl₂), dichlorodisilane (Si₂H₄Cl₂), tetraohlorodisilane (Si₂H₂Cl₄), hexachlorodisilane (Si₂Cl₆), and octachlorotrisilane (Si₃Cl₈).

25. The method of claim 19, wherein the lower-level silane-based gas lower than or equal to the disilane is selected from gases comprising at least one of monosilane (SiH₄) and disilane (Si₂H₆).
